(19) United States
(12) Patent Application Publication
(10) Pub. No.: US 2025/0234628 A1
(43) Pub. Date: Jul. 17, 2025

(54) LAYER STRUCTURE INCLUDING SILICIDE LAYER, METHOD OF MANUFACTURING THE SAME, AND SEMICONDUCTOR DEVICES AND ELECTRONIC DEVICES INCLUDING LAYER STRUCTURE

(71) Applicant: Samsung Electronics Co., Ltd., Suwon-si (KR)

(72) Inventors: Woonghyeon PARK, Suwon-si (KR); Haeryong KIM, Suwon-si (KR); Byunghoon NA, Suwon-si (KR); Jaeho LEE, Suwon-si (KR); Jooho LEE, Suwon-si (KR)

(73) Assignee: Samsung Electronics Co., Ltd., Suwon-si (KR)

(21) Appl. No.: 18/750,513

(22) Filed: Jun. 21, 2024

(30) Foreign Application Priority Data
Jan. 11, 2024 (KR) 10-2024-0004863

(51) Int. Cl. H01L 29/49; H01L 21/285; H01L 29/47

(52) U.S. Cl. CPC H10D 64/661; H01L 21/28518; H10D 64/64

(57) ABSTRACT

A layer structure including a silicide layer, a method of manufacturing the same, and a semiconductor device and electronic device including the layer structure are disclosed. The layer structure according to some examples embodiments includes a first material layer including silicon (Si), a second material layer disposed to face the first material layer and forming a Schottky barrier with the first material layer, a silicide layer provided between the first material layer and the second material layer, wherein the silicide layer includes binary silicide and ternary silicide.

### CROSS-REFERENCE TO RELATED APPLICATION

This application is based on and claims priority under 35 U.S.C. § 119 to Korean Patent Application No. 10-2024-0004863, filed on Jan. 11, 2024, in the Korean Intellectual Property Office, the disclosure of which is incorporated by reference herein in its entirety.

### BACKGROUND

### 1. Field

Example embodiments of the present disclosure relate to a semiconductor device including a silicide layer, and more specifically, to a layer structure including a semiconductor and a silicide layer, a manufacturing method thereof, and a semiconductor device and electronic device including the layer structure.

### 2. Description of the Related Art

Because an energy barrier at an interface between a semiconductor and a metal, that is, a Schottky barrier, affects the flow of electrons, the height of the Schottky barrier must be lowered to achieve low resistance.

The height of the Schottky barrier may be determined based on the potential required for electrons to move from a metal to a semiconductor. An energy difference at a metal-semiconductor interface between the Fermi level of a metal and a conduction band minimum of a semiconductor is called the n-type Schottky barrier.

One method to lower the Schottky barrier between a metal and a semiconductor (e.g., silicon) is to form silicide, which is a compound of silicon and metal, at a junction of the metal and silicon. As silicide is formed at a junction of a metal and silicon, an interface between the metal and silicon may be chemically more stable and have lower contact resistance than when the metal and silicon are in direct contact.

### SUMMARY

Provided are layer structures that reduce constant lattice mismatch.

Provided are layer structures capable of lowering a Schottky barrier height.

Provided are methods of manufacturing a layer structure.

Provided are semiconductor devices and electronic devices including the layer structure.

Additional aspects will be set forth in part in the description which follows and, in part, will be apparent from the description, or may be learned by practice of the presented embodiments of the disclosure.

According to an embodiment, a layer structure may include a first material layer including silicon (Si), a second material layer disposed to face the first material layer and forming a Schottky barrier with the first material layer, and a silicide layer between the first material layer and the second material layer, wherein the silicide layer comprises an order “n” silicide and order “n+1” or greater silicide.

In some embodiments, the silicide layer may include a first silicide layer between the first material layer and the second material layer, the first silicide layer including the order n+1 or greater silicide; and a second silicide layer between the first silicide layer and the second material layer, the second silicide layer including the order n silicide. In some embodiments, the first silicide layer may comprise a mixture of the order “n+1” or greater silicide and the order n silicide.

In some embodiments, the order “n+1” or greater silicide may have a composition formula of M1M2Siₓ, and the order n silicide may have a composition formula M2Siₓ, wherein M1 and M2 include different elements. In some embodiments, M1 has a first atomic radius R1, M2 has a second atomic radius R2, and the first atomic radius R1 is equal to or less than (1.15×R2), and M1 and M2 may have valence states that are compatible with each other. In some embodiments, M1 may include at least one of Co, Cr, Fe, Hf, Mn, Mo, Nb, Ni, Ru, Sc, Ta, Ti, V, W, Y or Zr, and M2 may include at least one of Sc, Ti, V, Co, Zr, Hf, or Y. In some embodiments, the second material layer may include one of M1 and M2 as a metal component. In some embodiments, order “n+1” or greater silicide may further comprises an additional metal component different from M1 and M2. In some embodiments, the ternary silicide may further include a metal component different from M1 and M2.

In some embodiments, the silicide layer may be provided between (100) plane of the first material layer and the second material layer.

In some embodiments, the first material layer may include at least one of an undoped silicon layer, a silicon layer doped with a p-type dopant, or a silicon layer doped with an n-type dopant.

According to an embodiment, a method of manufacturing a layer structure, the method includes distributing a first element on a first material layer, the first material layer comprising silicon (Si); forming a second material layer covering the first element on the first material layer, the second material layer comprising a metal component; and heat treating the second material layer such that a silicide including the first element is formed between the first and second material layers, wherein the first element is a material different from the metal component.

In some embodiments, the method may further comprise distributing a second element together with the first element on the first material layer, then forming the second material layer to cover the first and second elements, wherein the second element may be a different element from the first element.

In some embodiments, the first element may include at least one of Co, Cr, Fe, Hf, Mn, Mo, Nb, Ni, Ru, Sc, Ta, Ti, V, W, Y or Zr.

In some embodiments, the metal component may include a metal element, and the first element has a first atomic radius R1, and the metal element has a second atomic radius R2, wherein the first atomic radius R1 is equal to or less than (1.15×R2), and the first element and the metal element have valence electron states that are compatible with each other.

In some embodiments, the metal component may include at least one of Sc, Ti, V, Co, Zr, Hf, or Y.

In some embodiments, the heat treating is performed such that the silicide includes the first element, the metal component, and the silicon and a binary silicide including the metal component and the silicon.

According to an embodiment, a semiconductor device comprising the layer structure described above.

According to an embodiment, an electronic device comprising the layer structure and/or the semiconductor device described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a layer structure including a silicide layer, according to at least one example embodiment;

FIG. 2 is a three-dimensional diagram showing a bulk structure of ternary silicide when a composition of the first silicide layer in the layer structure of FIG. 1 is Hf:ZrSi;

FIG. 3 is a three-dimensional diagram showing a bulk structure of ternary silicide when a composition of the first silicide layer in the layer structure of FIG. 1 is Hf:Zr₅Si₃;

FIG. 4 is a graph showing results of a simulation conducted to confirm the degree of improvement in a lattice constant mismatch between a first material layer and a second silicide layer according to the type of interface modulation material (IMM) included in the first silicide layer in the layer structure of FIG. 1;

FIG. 5 is a graph showing a relationship between an average lattice constant mismatch and an n-type Schottky barrier height according to the concentration of Hf when the IMM included in the first silicide layer is Hf in the simulation to obtain the simulation result of FIG. 4;

FIG. 6 is a graph showing the separation of zirconium silicide (beta-phase ZrSi) with a basic composition of ZrSi in FIG. 5 and a ternary silicide including hafnium (Hf) as an IMM in the basic composition;

FIG. 7 is a graph showing the separation of zirconium silicide with a basic composition of Zr₅Si₃ in FIG. 5 and a ternary silicide including Hf as an IMM in the basic composition;

FIG. 8 is a bar graph showing the change in Schottky barrier height according to the type of IMM included in the first silicide layer in the simulation showing the simulation results of FIG. 4;

FIG. 9 is a bar graph showing the Schottky barrier height change between the first material layer and the second material layer according to the type of IMM included in the first silicide layer when other silicides are used instead of zirconium silicide in the simulation showing the simulation results of FIG. 4;

FIGS. 10 to 12 are graphs showing changes in average lattice constant mismatch according to the concentration of IMM included in the first silicide layer in the simulation showing the simulation results of FIG. 4;

FIGS. 13 to 19 are cross-sectional views and a plan view (FIG. 14) showing operations of a method of manufacturing a layer structure, according to at least one example embodiment;

FIG. 20 is a schematic cross-sectional view showing a structure of a field effect transistor to which a semiconductor device according to at least one example embodiment is applied;

FIG. 21 is a schematic cross-sectional view showing a structure of a field effect transistor to which a semiconductor device according to at least one example embodiment is applied;

FIG. 22 is a schematic diagram showing an image sensor to which a semiconductor device according to at least one example embodiment is applied;

FIG. 23 is a schematic cross-sectional view showing a structure of a field effect transistor according to at least one example embodiment;

FIG. 24 is a schematic cross-sectional view showing a structure of a field effect transistor according to at least one example embodiment;

FIG. 25 is a schematic perspective view showing a structure of a field effect transistor according to at least one example embodiment;

FIG. 26 is a schematic cross-sectional view showing a structure of the source/drain structure shown in FIG. 25;

FIG. 27 is a schematic block diagram of a display driver integrated circuit (DDI) and a display device including the DDI, according to at least one example embodiment;

FIG. 28 is a circuit diagram of a CMOS inverter according to at least one example embodiment;

FIG. 29 is a circuit diagram of a CMOS SRAM device according to at least one example embodiment;

FIG. 30 is a circuit diagram of a CMOS NAND circuit according to at least one example embodiment;

FIG. 31 is a block diagram showing an electronic device according to at least one example embodiment; and

FIG. 32 is a block diagram of an electronic device according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a layer structure including a silicide layer, a manufacturing method thereof, and a semiconductor device and electronic device including the layer structure will be described in detail with reference to the accompanying drawings. In the drawings, thicknesses of layers and regions may be exaggerated for clarification of the specification. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

The following embodiments described below are merely illustrative, and various modifications may be possible from the embodiments of the present disclosure. When an element or layer is referred to as being “on” or “above” another element or layer, the element or layer may be directly on another element or layer or intervening elements or layers. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “ . . . modules” denote units or modules that process at least one function or operation, and may be realized by and/or include processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

The connections of lines and connection members between constituent elements depicted in the drawings are examples of functional connection and/or physical or circuitry connections, and thus, in practical devices, may be expressed as replaceable or additional functional connections, physical connections, or circuitry connections.

The use of all examples or illustrative terms is simply for explaining the technical idea in detail, and the scope is not limited by the examples or illustrative terms unless limited by the claims.

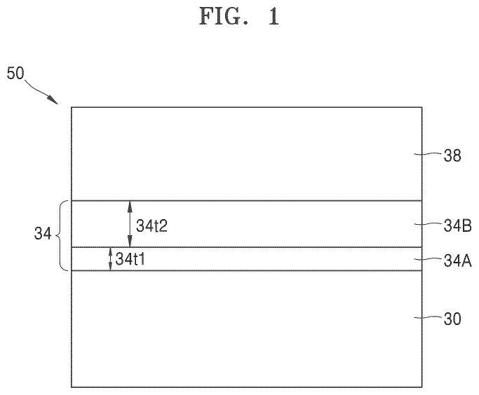

FIG. 1 shows a layer structure 50 including a silicide layer according to at least one example embodiment. The layer structure 50 of FIG. 1 may be a portion of a semiconductor device and thus may be considered as a semiconductor device or as a portion of a semiconductor device.

Referring to FIG. 1, the layer structure 50 including a silicide layer includes a first material layer 30, a silicide layer 34, and a second material layer 38 that are sequentially stacked. In at least one example, the first material layer 30 may include silicon (Si). As an example, the first material layer 30 may be a silicon layer and/or may include a silicon layer. As an example, the first material layer 30 may be a single layer or a multilayer composed of a plurality of layers. In at least one example, when the first material layer 30 is a single layer, the first material layer 30 may be a silicon layer or a material layer including silicon. In at least one example, the first material layer including silicon may be a silicon-rich material layer, but is not limited thereto. In at least one example, if the first material layer 30 is a multilayer, the layer in contact with the silicide layer 34 of the first material layer 30 may be a silicon layer.

In at least one example, the first material layer 30 may include a single crystal or polycrystalline silicon layer including at least a first dopant, or an undoped single crystal or polycrystalline silicon layer that does not include the first dopant. In at least one example, the first dopant may include an n-type conductive impurity or a p-type conductive impurity. In at least one example, the n-type conductive impurity may include a Group 5 element, for example, arsenic (As) or phosphorus (P), but is not limited thereto. In at least one example, the p-type conductive impurity may include a Group 3 element, for example, boron (B), but is not limited thereto.

In at least one example, a surface of the first material layer 30 facing the silicide layer 34 may be a surface having a low index facet or a surface having a high index facet, but is not limited thereto. In at least one example, the low index facet may include planes of (100), (111), and (110) but is not limited thereto. In at least one example, the high index facet may include planes of (021), (211), etc., but is not limited thereto. For example, the surface of the first material layer 30 facing the silicide layer 34 may be a (100) plane, but is not limited thereto. As an example, the silicide layer 34 may be formed directly on the (100) plane of the first material layer 30.

In at least one example, the silicide layer 34 may include a first silicide layer 34A and a second silicide layer 34B sequentially formed on the first material layer 30 in a direction towards the second material layer 38 but is not limited thereto. In at least one example, the silicide layer 34 may include silicon (Si) and at least one metal component. The metal component may be expressed as a metal element or a metallic element. In at least one example, a thickness 34t1 of the first silicide layer 34A may be less than a thickness 34t2 of the second silicide layer 34B but is not limited thereto. In at least one example, the thickness 34t1 of the first silicide layer 34A may be in a range from about 3 Å to about 30 Å and/or the thickness 34t2 of the second silicide layer 34B may be 10 nm or less, but the examples are not limited thereto.

In at least one example, the second silicide layer 34B may include an order “n” silicide and the first silicide layer 34A may have of an order n+1 or greater silicide. For example, in the case wherein the second silicide layer 34B includes a binary silicide (e.g., wherein n=2 such that the second silicide layer 34B includes a silicide of a metal component and silicon) the first silicide layer 34A may include a ternary silicide (e.g., wherein the first silicide layer 34A includes a silicide of two different metal components and silicon) and/or a quaternary silicide (e.g., where in the first silicide layer 34A includes a silicide of three different metal components and silicon).

For example, in at least one example, the first silicide layer 34A may include a first metal component, a second metal component, and silicon (Si). In other words, the first silicide layer 34A may include a ternary material having a composition expressed as M1_{z}M2_{y}Siₓ, wherein M1 and M2 respectively represent a metal element (or a metallic element) and may include different elements from each other. In at least one example, M1 may be the first metal component, and M2 may be the second metal component. In the “M1_{z}M2_{y}Siₓ”, ‘z’, ‘y’ and ‘x’ represent a compositional ratio of the respective elements, and ‘x’ may be, e.g., 1, 2, 3 . . . , but is not limited thereto. In this respect, the first silicide layer 34A may be referred to as a ternary silicide layer. In at least one example, one of M1 and M2 may be the same as the metal component included in the second silicide layer 34B and the second material layer 38 but is not limited thereto. The remainder one of M1 and M2 may be different from a metal component included in the second silicide layer 34B and a metal component included in the second material layer 38, but is not limited thereto. In at least one example, the remainder one of M1 and M2 may be different from the metal component included in the second silicide layer 34B and may be the same as the metal component included in the second material layer 38, but is not limited thereto. In at least one example, the first silicide layer 34A, the second silicide layer 34B, and the second material layer 38 may all include the M2, and the M1 may be included only in the first silicide layer 34A. In at least one example, the first and second silicide layers 34A and 34B may include the M2, the second material layer 38 may not include the M2, and the M1 may be included only in the first silicide layer 34A and the second material layer 38. In at least one example, the metal component among M1 and M2 that is not included in the second silicide layer 34B but is included in the first silicide layer 34A may be referred to as “silipant”, as “metal additive”, and/or as a silicide adding material (SAM). As the first silicide layer 34A includes the metal component that is not included in the second silicide layer 34B, a lattice mismatch between the first material layer 30 and the second silicide layer 34B is improved (reduced), which may be regarded as a result of adjusting an interface between the first material layer 30 and the second silicide layer 34B by the metal additive. In this regard, the metal component among M1 and M2 that is not included in the second silicide layer 34B but is included in the first silicide layer 34A may be referred to as an interface modulation material (IMM) and the first silicide layer 34A may be referred to as an interface modulation material layer. For case of description, the following description assumes the metal component M1 as the IMM material.

In at least one example, when M1 is the IMM, M1 may include one of Co, Cr, Fe, Hf, Mn, Mo, Nb, Ni, Ru, Sc, Ta, Ti, V, W, Y, Zr, and/or the like; but is not limited thereto. In at least one example, M2 may include, but is not limited to, one of Sc, Ti, V, Co, Zr, Hf, Y, and/or the like. For example, if the IMM is Hf and M2 is Zr, a composition of the ternary first silicide layer 34A may be HfzZrySix, and a composition of the second silicide layer 34B may be ZrySix. In at least one example, a first radius R1 of the metal element belonging to M1 may be less than or equal to a second radius R2 of the metal element belonging to M2, or may be greater than the second radius within 15%, but is not limited thereto. As an example, R1 may be 1.15×R2 or less, but is not limited thereto.

In at least one example, the metal element belonging to M1 may satisfy the radius condition and include a different metal element from the metal element belonging to M2, and the different metal element may have valence state compatible with the metal element belonging to M2, but is not limited thereto. As an example, the valence state may include the number of valence electrons.

In at least one example, the first silicide layer 34A may or may not have an entirely ternary composition. For example, the first silicide layer 34A may include both a ternary composition and a binary composition. For example, a portion of the first silicide layer 34A may include a binary silicide material, and binary and ternary silicide materials may coexist throughout the first silicide layer 34A. In at least one example, in the first silicide layer 34A, the ternary silicide material may be uniformly distributed throughout the first silicide layer 34A. In other words, the distribution concentration of the ternary silicide material throughout the first silicide layer 34A may be uniform (or substantially uniform). Expressed differently, the IMM may be distributed substantially uniformly in the first silicide layer 34A.

In at least one example, the first silicide layer 34A may include ternary or more silicide. For example, the first silicide layer 34A may include a quaternary silicide having a composition expressed as M1aM1bM2Six. Here, M1a may be a first IMM, and M1b may be a second IMM. In at least one example, M1a and M1b may be different materials (elements) from each other and may be one of the materials indicated by IMM.

In at least one example, the concentration (content) of IMM in the first silicide layer 34A may be about 40 atomic percent (at %) but is not limited thereto. As an example, the concentration of IMM may be greater than 0 and less than 20 at %, less than 30 at %, and/or less than 35 at %. The concentration of the IMM may be based on a metal included in the first silicide layer 34A. For example, if the composition of the first silicide layer 34A is (IMM) M2Si, the IMM concentration of 40 at % may correspond to IMM/(IMM+M2)=0.4. If the IMM in the first silicide layer 34A includes two different types of elements, the concentration of the IMM may denote a concentration including the two different types of elements. In at least one example, the second silicide layer 34B may be a layer (binary silicide layer) including a binary silicide (e.g., ScSi, ZrSi, TiSi, etc.) including only two types of elements, M2 and silicon (Si). In at least one example, the second silicide layer 34B may be entirely a binary silicide layer. However, in a process of forming the layer structure 50, ternary silicide may be unintentionally or unavoidably included in a region of the second silicide layer 34B, but the amount may be extremely small. For example, in at least one example, the ternary silicide may be undetectable and/or within a range of the noise in the detection. In this respect, the second silicide layer 34B may be regarded as a layer that does not include ternary silicide and may be expressed as substantially entirely a binary silicide layer.

In at least one example, the first and second silicide layers 34A and 34B may be formed continuously through a heat treatment process in a process of forming the layer structure 50. Accordingly, if forming layer upon layer through a deposition process, a physical boundary between the layers that may appear to not exist between the first and second silicide layers 34A and 34B. In other words, an interface between the first and second silicide layers 34A and 34B may be indistinct, but the examples are not limited thereto.

In this way, because the first silicide layer 34A having a ternary composition exists between the second silicide layer 34B and the first material layer 30, the crystal lattice mismatch between the first material layer 30 and the second silicide layer 34B may be improved (e.g., reduced). As the crystal lattice mismatch is improved, the Schottky barrier between the first material layer 30 and the second material layer 38 may also be lowered. In addition, as the first silicide layer 34A is provided, an interface formation energy between the first material layer 30 and a material layer formed thereon (e.g., the second silicide layer 34B) may be lowered. Therefore, the interface between the first material layer 30 and the material layer formed thereon may be more stable.

In at least one example, the second material layer 38 may be a material layer in which at least a surface in contact with the second silicide layer 34B is a metal surface. As an example, the second material layer 38 may be a single metal layer (e.g., a first metal layer) or may include the first metal layer. For example, the second material layer 38 may be a single layer or a multilayer and may include the first metal layer. In at least one example, if the second material layer 38 is a multilayer, a layer in contact with the second silicide layer 34B may be the first metal layer. That is, if the second material layer 38 is a multilayer, the first metal layer may be formed directly on the second silicide layer 34B. In at least one example, the first metal layer may include (e.g., share) a metal (e.g., M2) of the second silicide layer 34B. In at least one example, the first metal layer may be an M2 layer including M2 or may include the M2 layer. In at least one example, the first metal layer may be a layer including the M1 and/or may include the layer. In at least one example, if the second material layer 38 is a multilayer, the second material layer 38 may further include a second metal layer including a metal different from the metal of the first metal layer on the first metal layer, and another metal layer including a metal different from the metal of the second metal layer may further be provided on the second metal layer.

In at least one example, the first metal layer of the second material layer 38 may include a metal different from the metal included in the second silicide layer 34B. For example, the first metal layer of the second material layer 38 may include a metal that may be used in semiconductor wiring. In at least one example, the metal may include, but is not limited to, tungsten (W), aluminum (Al), titanium (Ti), and/or the like.

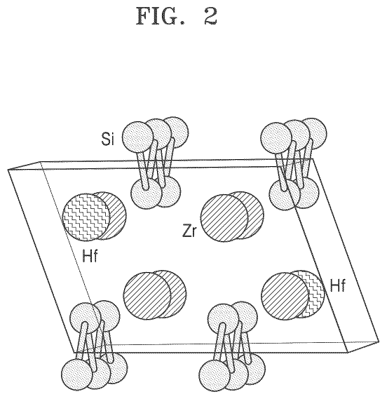

FIG. 2 shows a bulk structure of ternary silicide if the composition of the first silicide layer 34A is Hf:ZrSi.

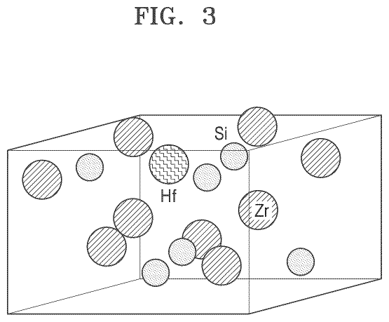

FIG. 3 shows a bulk structure of ternary silicide if the composition of the first silicide layer 34A is Hf:Zr5Si3.

In both FIGS. 2 and 3, Si is illustrated as the smaller element, and Hf and Zr are illustrated as the large elements with the step and line patterns, respectively.

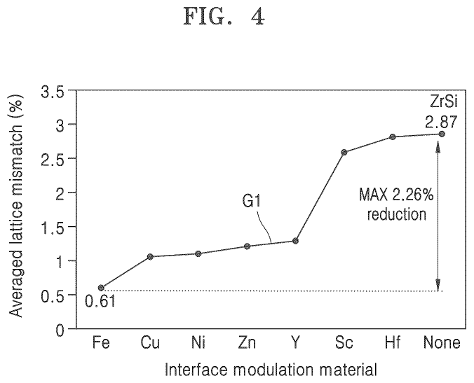

FIG. 4 shows results of a simulation conducted to confirm the degree of improvement in a lattice constant mismatch between the first material layer 30 and the second silicide layer 34B according to the type of IMM included in the first silicide layer 34A. In the simulation, the first material layer 30 was set as a silicon layer, the second material layer 38 was set as a zirconium (Zr) layer, the second silicide layer 34B was set as a ZrSi layer, the first silicide layer 34A was set as a ZrSi layer ((IMM) ZrSi layer) including an IMM, and the ZrSi layer was set as a relatively stable beta-phase ZrSi layer. Also, in the above simulation, Fe, Cu, Ni, Zn, Y, Sc, and Hf were used as the IMM.

In FIG. 4, a horizontal axis represents the type of IMM, and the vertical axis represents the average lattice constant mismatch between the first material layer 30 and the second silicide layer 34B. On the horizontal axis, “None” indicates a case when there is no IMM, that is, a case when the first silicide layer 34A does not include an IMM, which may correspond to a case when the silicide layer 34 includes only the second silicide layer 34B or a case when the entire silicide layer 34A is the second silicide layer 34B.

Referring to the first graph G1 of FIG. 4, the degree of average lattice constant mismatch varies depending on the type of IMM, and when the IMM is Fe, the lattice constant mismatch is the lowest, and when the IMM is Hf, the lattice constant mismatch is the highest. However, the degree of lattice constant mismatch when the IMM is Hf is lower than the lattice constant mismatch when the first silicide layer 34A does not include the IMM (“None”).

As a result, FIG. 4 shows that the presence of the first silicide layer 34A in the layer structure 50 improves the lattice constant mismatch between the first material layer 30 and the second silicide layer 34B. For example, without being limited to a specific theory, FIG. 4 shows that the lattice parameter of the first silicide layer 34A including an IMM intends to adjust the lattice parameters of the first material layer 30 and the second silicide layer 34B towards a mean therebetween, thereby improving (e.g., reducing) the lattice constant mismatch between the first material layer 30 and the second silicide layer 34B. Alternatively, because the interface between the first silicide layer 34A and the second silicide layer 34B may be indistinct, the region between the first silicide layer 34A and the second silicide layer 34B may have a lattice parameter between the lattice parameters of bulk (e.g., an internal region) of the first material layer 30 and the second silicide layer 34B such that the lattice constant mismatch between the first material layer 30 and the second silicide layer 34B is improved. In addition, the result of FIG. 4 shows that the lattice constant mismatch between the first material layer 30 and the second silicide layer 34B may be lowered by appropriately selecting the IMM included in the first silicide layer 34A.

As noted above, the difference between the first silicide layer 34A and the second silicide layer 34B in a material composition is that the first silicide layer 34A includes an IMM while the second silicide layer 34B does not include an IMM, and thus, the result in FIG. 4 may be considered to be due to the fact that IMM is included in the first silicide layer 34A. In this respect, the first silicide layer 34A may also be referred to as a lattice constant mismatch reduction layer, and the IMM included in the first silicide layer 34A may also be referred to as a lattice constant mismatch reduction material.

Also, as a result of the fact that the Schottky barrier height between the first material layer 30 and the second material layer 38 may be lowered as the lattice constant mismatch decreases, the first silicide layer 34A may also be referred to as a layer that reduces the Schottky barrier height and/or as a Schottky barrier reducing layer, and the IMM included in the first silicide layer 34A may also be referred to as a material that reduces the Schottky barrier height and/or a Schottky barrier reducing material.

Further, as the improving of the lattice constant mismatch and the lowering of the Schottky barrier between the first material layer 30 and the second silicide layer 34B may be seen as controlling (adjusting) and/or modulating interface characteristics between the first material layer 30 and the second silicide layer 34B, the first silicide layer 34A may also be referred to as an interface modulation layer and/or an interface control (or adjustment) layer, and the IMM included in the first silicide layer 34A may also be referred to as an interface modulation material and/or an interface control (or adjustment) material.

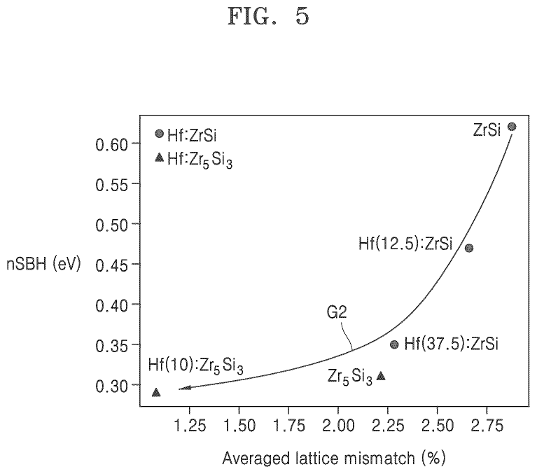

FIG. 5 shows a relationship between an average lattice constant mismatch and an n-type Schottky barrier height according to the concentration of Hf when the IMM included in the first silicide layer 34A is Hf in a simulation to obtain the simulation result of FIG. 4.

In FIG. 5, the horizontal axis represents the lattice constant mismatch between the first material layer 30 and the second silicide layer 34B, and the vertical axis represents the Schottky barrier height. In the simulation to obtain the results shown in FIG. 5, the first silicide layer 34A was set to include Hf as IMM in zirconium silicides (e.g., ZrSi, Zr5Si3, etc.) with different compositions, and Hf at different concentrations.

In FIG. 5, the figures in parentheses following Hf indicate the concentration of Hf. As an example, in FIG. 5, Hf(12.5):ZrSi represents a ternary silicide (e.g., HfZr7Si₈) including about 12.5 at % of hafnium (Hf) as an IMM in zirconium silicide with a basic composition of ZrSi, and Hf(37.5):ZrSi refers to a ternary silicide (e.g., Hf₃Zr₅Si₈) including about 37.5 at % Hf in IMM in zirconium silicide with a basic composition of ZrSi. Also, Hf(10):Zr₅Si₃ represents a ternary silicide (e.g., HfZr₉Si₆) including about 10 at % Hf in IMM in zirconium silicide with a basic composition of Zr₅Si₃.

Referring to the second graph G2 of FIG. 5, the lattice constant mismatch and Schottky barrier height are shown to vary depending on the concentration of Hf, regardless of the basic composition of zirconium silicide, and as the Hf concentration increases, the lattice constant mismatch and Schottky barrier height generally tends to be lowered than when Hf is not included (i.e., compared to the basic composition of zirconium silicide).

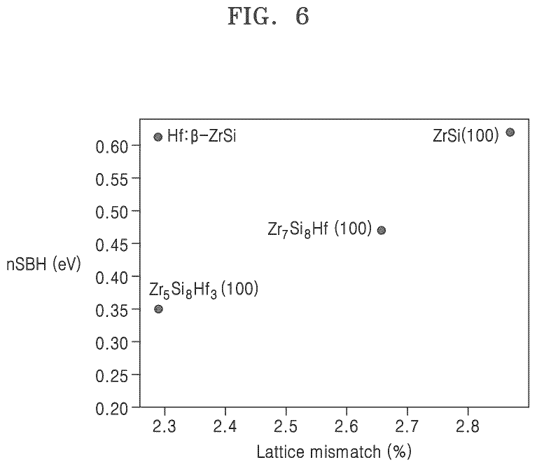

FIG. 6 shows separately zirconium silicide (ZrSi) with a basic composition of ZrSi, a ternary silicide (e.g., HfZr₇Si₈) including about 12.5 at % of Hf as IMM in the basic composition, and a ternary silicide (e.g., Hf₃Zr₅Si₈) including about 37.5 at % of Hf.

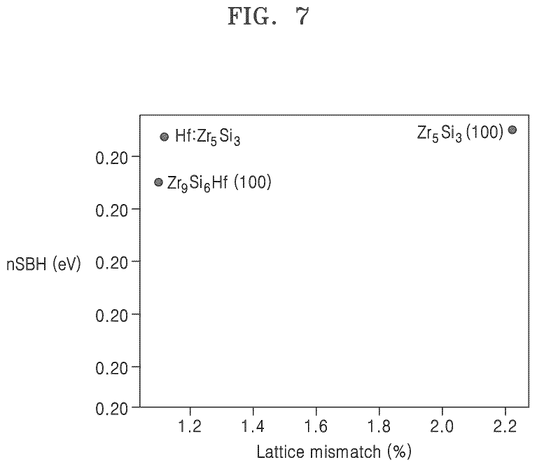

FIG. 7 shows separately zirconium silicide with a basic composition of Zr₅Si₃ in FIG. 5 and a ternary silicide (e.g., HfZr₉Si₆) including about 10 at % Hf as IMM in the basic composition.

In FIGS. 6 and 7, the (100) next to the silicide material indicates that the silicide material is formed on a (100) plane of a Si layer.

Referring to FIGS. 6 and 7, as the basic composition of zirconium silicide changes, the degree of reduction in lattice constant mismatch and the Schottky barrier height of ternary zirconium silicide including IMM also changes. However, no matter what the basic composition of zirconium silicide, the lattice constant mismatch and Schottky barrier height of the ternary silicide with IMM added to the basic composition are lower than the lattice mismatch and Schottky barrier height of silicide that has the basic composition and does not include IMM. In addition, the lattice constant mismatch and Schottky barrier height of the ternary silicide generally tend to decrease as the concentration of IMM increases.

As shown in FIGS. 5 to 7, the ternary first silicide layer 34A is provided between the first material layer 30 and the second silicide layer 34B, the lattice constant mismatch between the first material layer 30 and the second silicide layer 34B may be reduced. Accordingly, the interface formation energy between the first material layer 30 and the second silicide layer 34B may also be lowered. Because the degree of reduction in lattice constant mismatch varies depending on the composition of the first silicide layer 34A, the degree of reduction in the interface formation energy between the first material layer 30 and the second silicide layer 34B may also vary depending on the composition of the first silicide layer 34A.

Tables 1 and 2 below summarize the simulation results (lattice constant mismatch and Schottky barrier height change) shown in FIGS. 5 to 7, and also show the interface formation energy between the first material layer 30 and the second silicide layer 34B.

Table 1 summarizes the simulation results when the ternary first silicide layer 34A is zirconium silicide with a basic composition of ZrSi and Hf is included (added) as an IMM, and Table 2 summarizes the simulation results when the ternary first silicide layer 34A includes zirconium silicide with a basic composition of Zr₅Si₃ and Hf as the IMM.

TABLE 1

| | Lattice mismatch | Interface formation E | nSBH |
|---|---|---|---|
| Composition | (%) | (eV/Å²) | (eV) |
| ZrSi (100) | 2.87 | −0.17 | 0.56 |
| Zr₇Si₈Hf | 2.66 | −0.19 | 0.47 |
| Zr₅Si₈Hf₃ | 2.29 | −0.18 | 0.35 |

TABLE 2

| | Lattice mismatch | Interface formation E | nSBH |
|---|---|---|---|
| Composition | (%) | (eV/Å²) | (eV) |
| Zr₅Si₃ (100) | 2.22 | −0.16 | 0.31 |
| Zr₉Si₆Hf | 1.40 | −0.20 | 0.21 |

As explained with reference to FIGS. 5 to 7, Tables 1 and 2 show that as the ternary first silicide layer 34A is provided, the lattice constant mismatch, Schottky barrier height, and interface formation energy are lowered or reduced than when only silicide with a binary basic composition is provided.

Also, Tables 1 and 2 show that the degree of reduction and lowering in lattice constant mismatch, Schottky barrier height, and interface formation energy vary depending on the composition of the ternary first silicide layer 34A.

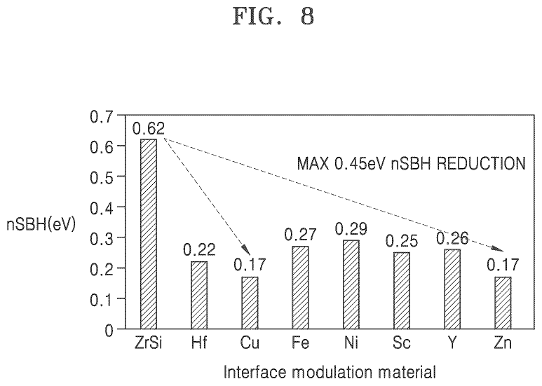

FIG. 8 shows the Schottky barrier height change according to the type of IMM included in the first silicide layer 34A in the simulation showing the simulation results of FIG. 4.

In FIG. 8, the horizontal axis represents the type of IMM, and the vertical axis represents the height of the Schottky barrier. On the horizontal axis, “ZrSi” represents zirconium silicide not including an IMM (e.g., when the first silicide layer 34A does not include an IMM or when the entire silicide layer 34 is the second silicide layer 34B) and the rest represents a zirconium silicide with the identified IMM.

Referring to FIG. 8, if the first silicide layer 34A does not include an IMM (ZrSi), the Schottky barrier height between the first material layer 30 and the second material layer 38 is about 0.62, however if the first silicide layer 34A includes an IMM (Hf, Cu, Fe, Ni, Sc, Y, Zn), the Schottky barrier height becomes much lower than 0.62. If the IMM included in the first silicide layer 34A is Cu or Zn, the Schottky barrier height between the first material layer 30 and the second material layer 38 is lowered to about 0.17.

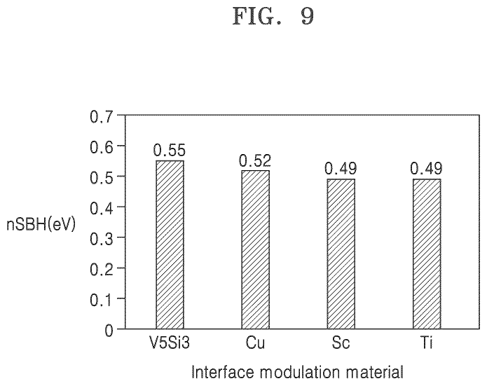

FIG. 9 shows the change in the Schottky barrier height between the first material layer 30 and the second material layer 38 according to the type of IMM included in the first silicide layer 34A if other silicide is used instead of zirconium silicide in the simulation showing the simulation results of FIG. 4.

The result of FIG. 9 shows that in the simulation of FIG. 4, the second material layer 38 is set to a vanadium (V) layer, the second silicide layer 34B is set to a V₅Si₃ layer, the first silicide layer 34A is set to IMM is set to a V₅Si₃ layer ((IMM) V₅Si₃ layer) including an IMM.

In FIG. 9, the horizontal axis represents the type of IMM, and the vertical axis represents the height of the Schottky barrier. On the horizontal axis, “V₅Si₃” represents vanadium silicide not including an IMM (e.g., a case when the first silicide layer 34A does not include an IMM, or when the entire silicide layer 34 is the second silicide layer 34B). The remainder (Cu, Sc, or Ti) on the horizontal axis represents examples of V₅Si₃ including some of the IMMs that may be included in the first silicide layer 34A. On the horizontal axis, the IMM may represent the first silicide layer 34A including the IMM. For example, “Cu” on the horizontal axis may represent the first silicide layer 34A including Cu as an IMM (e.g., vanadium silicide including Cu).

Referring to FIG. 9, if the first silicide layer 34A does not include an IMM (V₅Si₃), the Schottky barrier height between the first material layer 30 and the second material layer 38 is about 0.55. However, if the first silicide layer 34A includes an IMM (Cu, Sc, or Ti), the Schottky barrier height between the first material layer 30 and the second material layer 38 is lower than 0.55, and if the IMM is Sc or Ti, the Schottky barrier height is reduced to about 0.49.

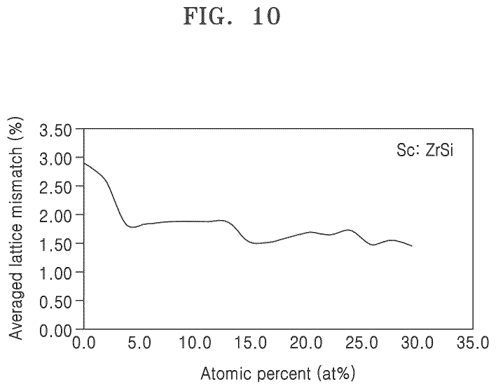

FIGS. 10 to 12 show changes in average lattice constant mismatch according to the content of IMM included in the first silicide layer 34A in the simulation showing the simulation results of FIG. 4.

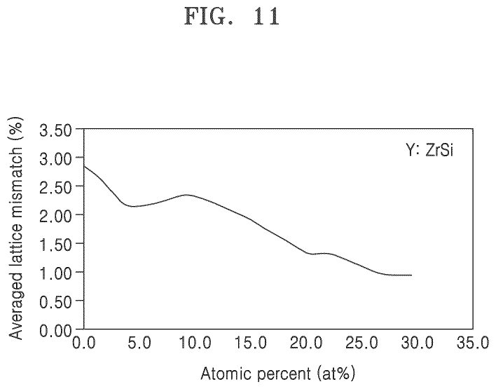

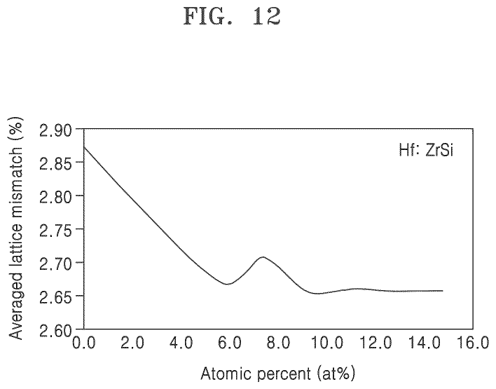

FIG. 10 is a result if the IMM is Sc (scandium), FIG. 11 is a result if the IMM is Y (yttrium), and FIG. 12 is a result if the IMM is Hf(hafnium).

In FIGS. 10 to 12, the horizontal axis represents the content of IMM, and the vertical axis represents the average lattice constant mismatch.

Referring to FIGS. 10 to 12, the degree of reduction in lattice constant mismatch varies depending on the type of IMM, but the lattice constant mismatch generally tends to decrease as the IMM content increases regardless of the type of IMM.

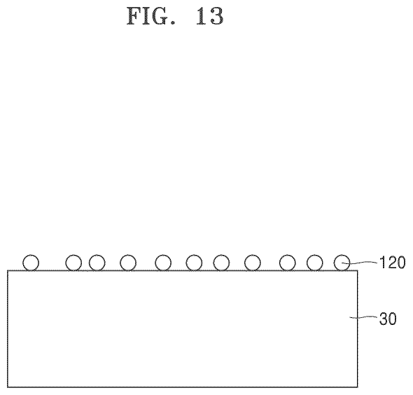

FIGS. 13 to 17 show operations of a method of manufacturing a layer structure according to an embodiment. Like reference numerals indicate elements that are identical to the elements of FIG. 4, and description thereof will be omitted.

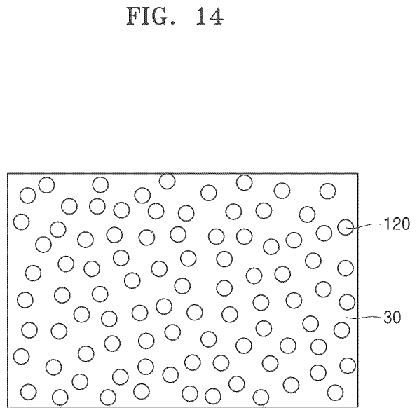

Referring to FIG. 13, IMMs 120 are distributed on an upper surface of the first material layer 30. The IMMs 120 may be uniformly distributed over an entire upper surface of the first material layer 30 as shown in FIG. 14 but are not limited thereto. In at least one example, the IMMs 120 may be distributed in a spray method evenly on the upper surface of the first material layer 30. In at least one example, the IMM 120 may be spread on the upper surface of the first material layer 30 using an atomic layer deposition (ALD) method but is not limited thereto.

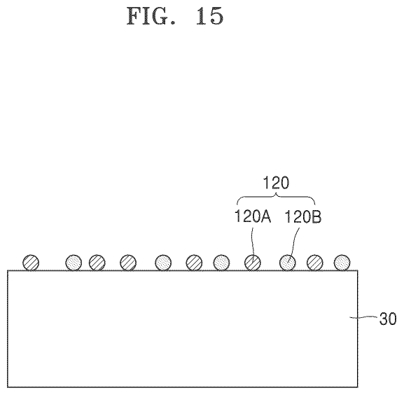

The IMM 120 may be the same as the IMM included in the first silicide layer 34A of FIG. 4 but is not limited thereto. In at least one example, the IMM 120 may be a single element, but may also be in the form of a molecule including the single element. In at least one example, the IMM 120 may include multiple different types of materials. As an example, the IMM 120 may include a first element 120A and a second element 120B as shown in FIG. 15 but is not limited thereto. The second element 120B may be a different element from the first element 120A. In at least one example, the plurality of types of materials may be the elements illustrated as IMM in the description of FIG. 4 but are not limited thereto. In at least one example, the first and second elements 120A and 120B may be included in the elements illustrated as the IMM in FIG. 4. For example, the first element 120A may include Hf among the elements illustrated as the IMM in the description of FIG. 4, and the second element 120B may include Cu or Zn. In at least one example, when the IMM 120 includes the plurality of types of materials (elements), the distribution density of each material may be the same or different from each other, and each material may be distributed substantially evenly on the upper surface of the first material layer 30.

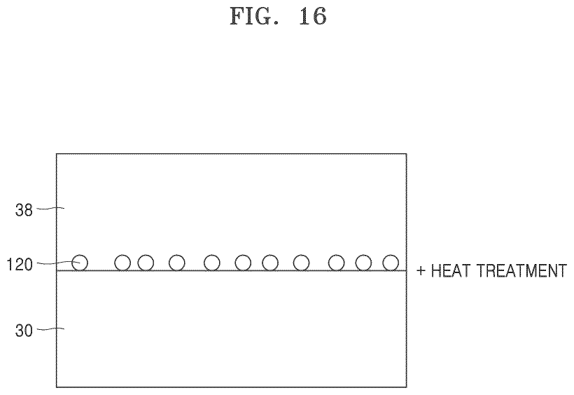

Next, as shown in FIG. 16, the second material layer 38 covering the IMM 120 is formed on the first material layer 30. The second material layer 38 may be formed to cover an entire upper surface of the IMM 120 and the first material layer 30. After forming the second material layer 38, the resultant product in which the second material layer 38 is formed is heat treated. The heat treatment may be a heat treatment to form a silicide layer between the first material layer 30 and the second material layer 38. In at least one example, the heat treatment may be performed at a temperature lower than 500 degrees but the examples are not limited thereto.

The first material layer 30 includes silicon and the second material layer 38 includes a metal, and thus, the silicon of the first material layer 30 diffuses into the second material layer 38 by the heat treatment. As a result, a lower layer of the second material layer 38 is combined with silicon and is silicided. That is, the lower layer of the second material layer 38 may be a silicide layer.

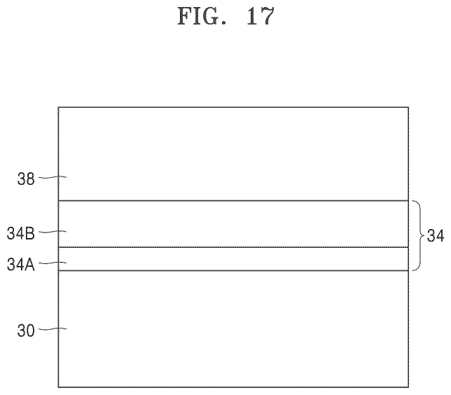

As a result, as shown in FIG. 17, the heat treatment forms a layer structure in which the first material layer 30, the silicide layer 34, and the second material layer 38 are sequentially stacked.

The silicidation process may begin from a lower part (bottom) of the second material layer 38, and because the IMM 120 is distributed on the upper surface of the first material layer 30, the initial or first stage of the silicidation may be seen as a stage in which the IMM 120, silicon, and a metal are combined to create ternary silicide ((IMM)M2Si). Because the IMM 120 is distributed on the upper surface of the first material layer 30, the first silicide layer 34A including ternary silicide may be formed on the upper surface of the first material layer 30 by the first stage of the silicidation process. All of the IMMs 120 distributed on the upper surface of the first material layer 30 may be used to form the first silicide layer 34A.

In the first silicide layer 34A, a composition of which may be expressed as (IMM)M2Si, the concentration of IMM relative to M2 may be about 40 at % (IMM:M2=0.4:1) but is not limited thereto. In at least one example, the concentration of IMM may be greater than 0 and 20 at % or less, 30 at % or less, or 35 at % or less. As described below, if the IMM includes two or more different types of elements, the concentration range of the IMM described above may be a range that includes all of the two or more different types of elements. For example, if the concentration of the IMM is 20 at % and the IMM includes two different types of elements, the concentration of one element may be 10 at % (or 5 at %), and the concentration of the remaining element may be 10 at % (or 15at %).

As shown in FIGS. 13 to 15, when the IMM 120 is distributed on the upper surface of the first material layer 30, the distribution amount of the IMM 120 may be determined in consideration of the concentration range of the IMM 120 in the first silicide layer 34A described above.

As shown in FIG. 15, if the IMM 120 includes the first and second elements 120A and 120B different from each other, in the first stage of silicidation, the first silicide layer 34A including quaternary silicide may be formed on the upper surface of the first material layer 30.

The silicidation may continue without interruption even after the first silicide layer 34A is formed, and this may be regarded as the second stage of the silicidation. In the second stage of silicidation, silicon and metal are combined to produce binary silicide (M2Si) without the IMM 120. As a result, the binary second silicide layer 34B may be formed on the first silicide layer 34A.

Due to the silicidation, a portion of a thickness of a lower layer of the second material layer 38 may be changed to the silicide layer 34. In at least one example, if the thickness of the second material layer 38 is thin enough to be entirely silicided during the silicide process, the entire second material layer 38 may be changed into a silicide layer. In this case, a separate metal layer or conductive layer may be formed on the entirely silicided second material layer 38. In at least one example, the metal layer may include a metal used in semiconductor wiring. In at least one example, the metal may include, but is not limited to, tungsten (W), aluminum (Al), and titanium (Ti). In at least one example, the separate metal layer or conductive layer may be formed on the second material layer 38 even when the entire second material layer 38 is not changed into a silicide layer, but the present disclosure is not limited thereto.

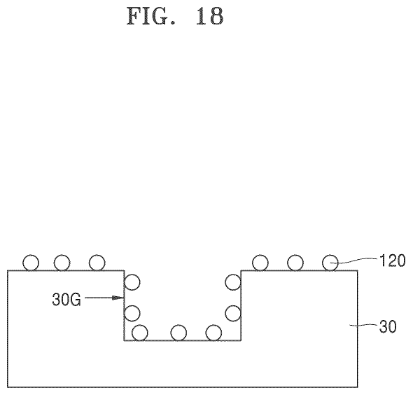

In at least one example, as illustrated in FIG. 18, the first material layer 30 may include a groove 30G. Therefore, in the process of positioning (depositing) the IMM 120 on the first material layer 30, the IMM 120 may also be positioned on side and lower surfaces of the groove 30G.

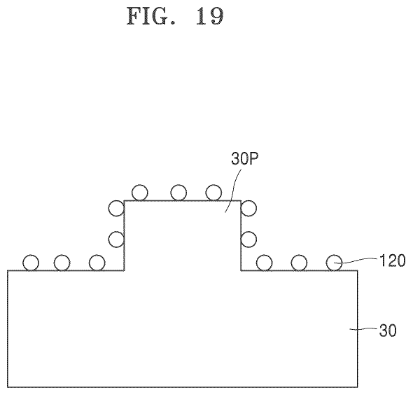

In at least one example, as illustrated in FIG. 19, the first material layer 30 may include a protrusion 30P that protrudes higher than the upper surface thereof. Therefore, in the process of positioning the IMM 120 on the first material layer 30, the IMM 120 may also be positioned on upper and side surfaces of the protrusion 30P.

In the case of FIGS. 18 and 19, subsequent processes may be performed as described with reference to FIGS. 15 to 17.

If the layer structure 50 according to the example embodiments described above is used, a contact resistance between the metal layer and the semiconductor layer may be lowered. Therefore, the layer structure 50 may be applied to next-generation semiconductor memory devices or logic devices.

The logic devices may perform calculation and control, and memory devices may perform storing information. The logic devices may be applied to micro components, analog Ics, logic Ics, etc. Analog Ics may include power semiconductors, image sensors, touch controllers, etc. Logic Ics may include DDI (Display Driver IC), T-CON, media IC, AP (Application Processor), automotive semiconductors, etc. Memory devices may include DRAM, SRAM, NAND memory, etc.

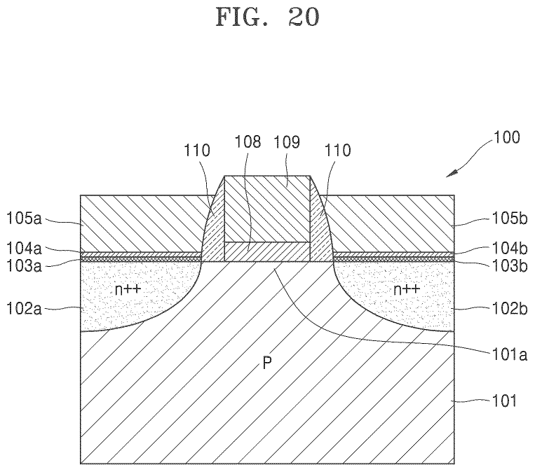

The layer structure 50 described above may be applied to various devices, such as field effect transistors. For example, FIG. 20 is a schematic cross-sectional view showing the structure of a field effect transistor 100 according to some embodiments.

Referring to FIG. 20, the field effect transistor 100 may include a well region 101 doped with a first conductivity type material (e.g., one of a P-type or an N-type), a source region 102a doped with a second conductivity type material (e.g., the other of the P-type or N-type) that is electrically opposite to the first conductivity type material, a drain region 102b doped with a second conductive material, a ternary first silicide layer 103a disposed on the source region 102a, a ternary second silicide layer 103b disposed on the drain region 102b, a binary third silicide layer 104a disposed on the first silicide layer 103a, a binary fourth silicide layer 104b disposed on the second silicide layer 103b, a source electrode 105a disposed on the third silicide layer 104a, a drain electrode 105b disposed on the fourth silicide layer 104b, a gate insulating film 108 disposed on the well region 101, and a gate electrode 109 disposed on the gate insulating film 108.

The source region 102a and the drain region 102b may correspond to the first material layer 30 including silicon of FIG. 1. The third silicide layer 104a and the fourth silicide layer 104b may correspond to the second silicide layer 34B of the layer structure 50 illustrated in FIG. 1. As an example, the third silicide layer 104a and the fourth silicide layer 104b may include the metal and silicon of the second silicide layer 34B illustrated in the description of the layer structure 50 in FIG. 1 but is not limited thereto. The ternary first silicide layer 103a and the ternary second silicide layer 103b may correspond to the first silicide layer 34A of the layer structure 50 illustrated in FIG. 1, and may include the ternary silicide illustrated by the first silicide layer 34A in FIG. 1. The source electrode 105a and the drain electrode 105b may correspond to the second material layer 38 of the layer structure 50 illustrated in FIG. 1, and may include a conductive material as illustrated by the second material in FIG. 1.

In at least one example, the source electrode 105a and the drain electrode 105b may respectively include a first conductive material and a second conductive material, wherein one of the first conductive material and the second conductive material may be a P-type material (P-type dopant), and the other may be an N-type material (N-type dopant), but the material is not limited thereto.

In FIG. 20, it is shown that the well region 101 is doped with a P-type dopant and the source region 102a and the drain region 102b are doped with an N-type dopant. However, this is only an example and the well region 101 may be doped with an N-type dopant and the source region 102a and the drain region 102b may be doped with a P-type dopant. In at least one example, the source region 102a and drain region 102b may be undoped regions. The well region 101 may be doped at a relatively low concentration in a range of about 10¹⁴/cm³ to about 10¹⁸/cm³, and the source region 102a and drain region 102b may be doped at a relatively high concentration of about 10¹⁹/cm³ or more to reduce a depletion width.

The source region 102a and the drain region 102b may be disposed on both sides of an upper part of the well region 101. For example, after forming the well region 101 by doping the semiconductor substrate with an N-type dopant, the source region 102a and the drain region 102b may be formed by doping both sides of an upper surface of the semiconductor substrate with an N-type dopant. The well region 101 may include a channel region 101a between the source region 102a and the drain region 102b. The channel region 101a may be doped with a first conductive type material like the well region 101. The source region 102a and the drain region 102b may be disposed apart from each other with the channel region 101a therebetween.

The first silicide layer 103a and the second silicide layer 103b may be disposed apart from each other with the gate insulating film 108 therebetween.

The third silicide layer 104a and the fourth silicide layer 104b may reduce contact resistance. The third silicide layer 104a and the fourth silicide layer 104b may be disposed apart from each other with the gate insulating film 108 therebetween.

By using the first silicide layer 103a, the lattice constant mismatch between the third silicide layer 104a and the source region 102a may be less than when the first silicide layer 103a is not present, and the Schottky barrier between the source region 102a and the source electrodes 105a may also be less than when the first silicide layer 103a is not present.

Due to the second silicide layer 103b, the lattice constant mismatch between the fourth silicide layer 104b and the drain region 102b may be less than when the second silicide layer 103b is not present, and the Schottky barrier between the drain region 102b and the drain electrodes 105b may also be less than when the second silicide layer 103b is not present.

A lower surface of the first silicide layer 103a may directly contact the source region 102a, and an upper surface of the first silicide layer 103a may directly contact the third silicide layer 104a. A lower surface of the second silicide layer 103b may be in direct contact with the drain region 102b, and an upper surface of the second silicide layer 103b may be in direct contact with the fourth silicide layer 104b.

The source electrode 105a disposed on the third silicide layer 104a and the drain electrode 105b disposed on the fourth silicide layer 104b may correspond to the second material layer 38 of the layer structure 50 illustrated in FIG. 1. As an example, the source electrode 105a and the drain electrode 105b may include the same metal as the second material layer 38 of the layer structure 50 of FIG. 1 but are not limited thereto.

Accordingly, a layer structure including the sequentially stacked source region 102a, first silicide layer 103a, third silicide layer 104a, and source electrode 105a may correspond to the layer structure 50 of FIG. 1. A layer structure including the sequentially stacked drain region 102b, second silicide layer 103b, fourth silicide layer 104b, and drain electrode 105b may also correspond to the layer structure 50 of FIG. 1.

The source electrode 105a and the drain electrode 105b may be disposed apart from each other with the gate electrode 109 therebetween.

The gate insulating film 108 may be disposed on an upper surface of the well region 101, particularly on an upper surface of the channel region 101a. The gate insulating film 108 may include at least one dielectric material, e.g., at least one of SiO₂, SiNₓ, HfO₂, and Al₂O₃. The gate electrode 109 disposed on the gate insulating film 108 may include polysilicon or the same metal material as the metal material of the source electrode 105a and the drain electrode 105b.

In at least one example, the field effect transistor 100 may further include a spacer 110 surrounding sidewalls of the gate insulating film 108 and the gate electrode 109. The spacer 110 may prevent the gate insulating film 108 and the gate electrode 109 from directly contacting the source electrode 105a and the drain electrode 105b. The spacer 110 may include an insulating material, such as at least one of SiO₂, SiNx, etc., but is not limited thereto.

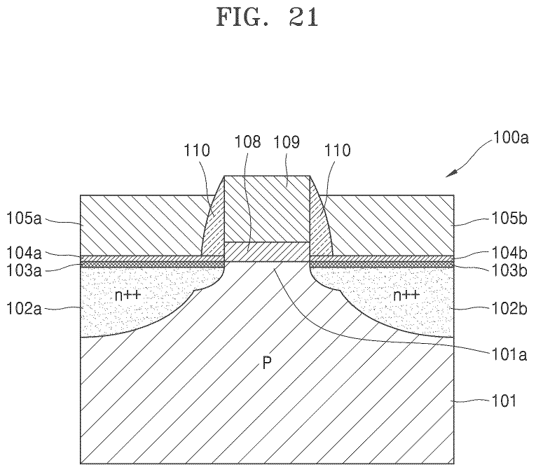

FIG. 21 is a schematic cross-sectional view showing a structure of a field effect transistor according to another embodiment. In the field effect transistor 100 illustrated in FIG. 20, the upper surfaces of the well region 101, source region 102a, and drain region 102b are located on the same plane, and the third and fourth silicide layers 104a and 104b extend to contact side surfaces of the spacer 110. On the other hand, in the field effect transistor 100a illustrated in FIG. 21, the third and fourth silicide layers 104a and 104b extend to contact lower surfaces of the spacer 110. To this end, the upper surface of the well region 101 may be formed higher than the upper surfaces of the source region 102a and the drain region 102b. The third and fourth silicide layers 104a and 104b may extend to an interface between the spacer 110 and the gate insulating film 108 along the lower surface of the spacer 110. In this case, the first silicide layer 103a and the second silicide layer 103b may also extend to the interface between the spacer 110 and the gate insulating film 108.

In at least one example, the field effect transistor 100 of FIG. 20 or the field effect transistor 100a of FIG. 21 may be employed in an image sensor but is not limited thereto.

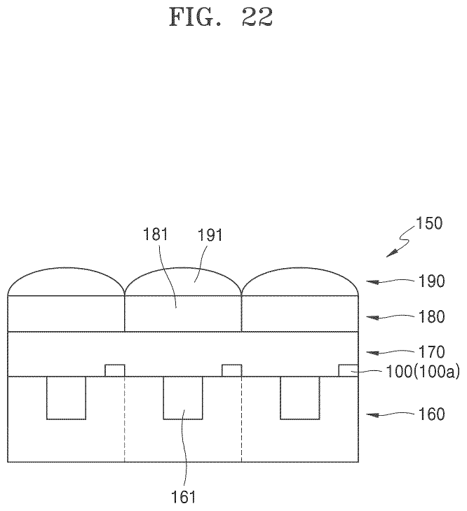

FIG. 22 is a schematic diagram showing an image sensor 150 according to some embodiments.

Referring to FIG. 22, the image sensor 150 may include an optical sensor array 160 in which optical sensors 161 configured to sense light are arranged, a color filter array 180 in which color filters 181 that filter light by color are arranged, a micro lens array 190 in which micro lenses 191 that focus light for each pixel are arranged, and a driving layer 170 including the field effect transistor 100 illustrated in FIG. 20 (or the field effect transistor 100a illustrated in FIG. 21) but is not limited thereto. The image sensor 150 may generate an electrical image signal based on the intensity of incident light. The image sensor 150 may be applied to various multimedia devices having an image capture function.

In at least one example, the image sensor 150 may be applied to cameras, such as mobile phones, smartphones, tablets, smart tablets, and laptops, but is not limited thereto.

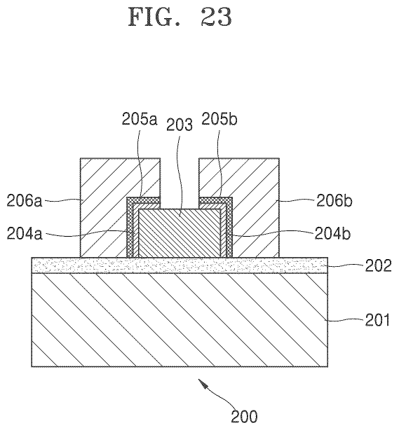

FIG. 23 is a schematic cross-sectional view showing a structure of a field effect transistor 200 according to another embodiment.

Referring to FIG. 23, the field effect transistor 200 may include a gate electrode 201, a gate insulating film 202 disposed on the gate electrode 201, a channel layer 203 disposed on the gate insulating film 202, a source electrode 206a disposed on one side of the channel layer 203 and electrically contacting the channel layer 203, a drain electrode 206b disposed on the other side of the channel layer 203 and electrically contacting the channel layer 203, a binary fifth silicide layer 205a disposed between the channel layer 203 and the source electrode 206a, a binary sixth silicide layer 205b disposed between the channel layer 203 and the drain electrode 206b, a ternary seventh silicide layer 204a disposed between the fifth silicide layer 205a and the channel layer 203, and a ternary eighth silicide layer 204b between the sixth silicide layer 205b and the channel layer 203.

In at least one example, the channel layer 203 may correspond to the first material layer 30 of the layer structure 50 illustrated in FIG. 1. In at least one example, the channel layer 203 may include, but is not limited to, undoped silicon. In at least one example, the source electrode 206a and the drain electrode 206b may correspond to the second material layer 38 of the layer structure 50 illustrated in FIG. 1.

In at least one example, the fifth silicide layer 205a and the sixth silicide layer 205b may correspond to the second silicide layer 34B of the layer structure 50 illustrated in FIG. 1. The fifth silicide layer 205a may extend from one side of the channel layer 203 to a portion of an upper surface of the channel layer 203. The sixth silicide layer 205b may extend from the other side of the channel layer 203 to another portion of an upper surface of the channel layer 203 so as not to contact the fifth silicide layer 205a. Accordingly, the fifth and sixth silicide layers 205a and 205b may be bent at about 90 degrees between the side surfaces and the upper surface of the channel layer 203.

In at least one example, the seventh silicide layer 204a and the eighth silicide layer 204b may correspond to the first silicide layer 34A of the layer structure 50 illustrated in FIG. 1.

As a result, a layer structure including the channel layer 203, the seventh silicide layer 204a, the fifth silicide layer 205a, and the source electrode 206a sequentially stacked in lateral and vertical directions may correspond to the layer structure 50 illustrated in FIG. 1. A layer structure including the channel layer 203, the eighth silicide layer 204b, the sixth silicide layer 205b, and the drain electrode 206b sequentially stacked in the lateral and vertical directions may also correspond to the layer structure 50 illustrated in FIG. 1.

The seventh silicide layer 204a may extend from one side of the channel layer 203 to a portion of the upper surface of the channel layer 203. The eighth silicide layer 204b may extend from the other side of the channel layer 203 to another portion of the upper surface of the channel layer 203 so as not to contact the seventh silicide layer 204a. Accordingly, the seventh and eighth silicide layers 204a and 204b may be bent at about 90 degrees between the side surfaces and the upper surface of the channel layer 203.

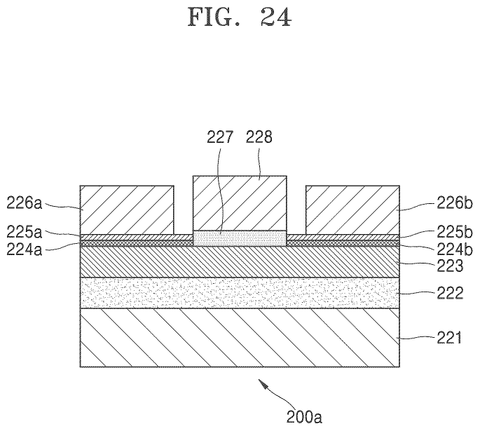

FIG. 24 is a schematic cross-sectional view showing a structure of a field effect transistor 200a according to another embodiment.

The field effect transistor 200 of FIG. 23 has a lower gate structure in which the gate electrode 201 is disposed below the channel layer 203, but the field effect transistor 200a shown in FIG. 24 has an upper gate structure.

Referring to FIG. 24, the field effect transistor 200a may include a substrate 221, an insulating layer 222 disposed on an upper surface of the substrate 221, a channel layer 223 disposed on an upper surface of the insulating layer 222, a gate insulating film 227 disposed on a region of an upper surface of the channel layer 223, a gate electrode 228 disposed on an upper surface of the gate insulating film 227, ternary ninth and tenth silicide layers 224a and 224b respectively disposed on different regions of the upper surface of the channel layer 223, a binary eleventh silicide layer 225a disposed on an upper surface of the ninth silicide layer 224a, a twelfth silicide layer 225b disposed on an upper surface of the tenth silicide layer 224b, a source electrode 226a disposed on an upper surface of the eleventh silicide layer 225a, and a drain electrode 226b disposed on an upper surface of the twelfth silicide layer 225b.

In at least one example, the channel layer 223 may correspond to the first material layer 30 of the layer structure 50 illustrated in FIG. 1. In at least one example, the channel layer 223 may include undoped silicon.

In at least one example, the ninth silicide layer 224a and the tenth silicide layer 224b may correspond to the first silicide layer 34A of the layer structure 50 illustrated in FIG. 1 but are not limited thereto. The ninth silicide layer 224a and the tenth silicide layer 224b may be disposed apart from each other with the gate insulating layer 227 therebetween. A lower surface of the ninth silicide layer 224a may be in direct contact with the channel layer 223, and the upper surface of the ninth silicide layer 224a may be in direct contact with the eleventh silicide layer 225a. A lower surface of the tenth silicide layer 224b may be in direct contact with the channel layer 223, and the upper surface of the tenth silicide layer 224b may be in direct contact with the twelfth silicide layer 225b.

In at least one example, the binary eleventh silicide layer 225a and the binary twelfth silicide layer 225b may correspond to the second silicide layer 34B of the layer structure 50 illustrated in FIG. 1. The eleventh silicide layer 225a and the twelfth silicide layer 225b may be disposed apart from each other with the gate insulating film 227 therebetween.

In at least one example, the source electrode 226a and the drain electrode 226b may correspond to the second material layer 38 of the layer structure 50 illustrated in FIG. 1.

Accordingly, a layer structure including the sequentially stacked channel layer 223, the ninth silicide layer 224a, the eleventh silicide layer 225a, and the source electrode 226a may correspond to the layer structure 50 illustrated in FIG. 1. A layer structure including the sequentially stacked channel layer 223, the tenth silicide layer 224b, the twelfth silicide layer 225b, and the drain electrode 226b may also correspond to the layer structure 50 illustrated in FIG. 1.

The source electrode 226a and the drain electrode 226b may be disposed apart from each other with the gate electrode 228 therebetween.

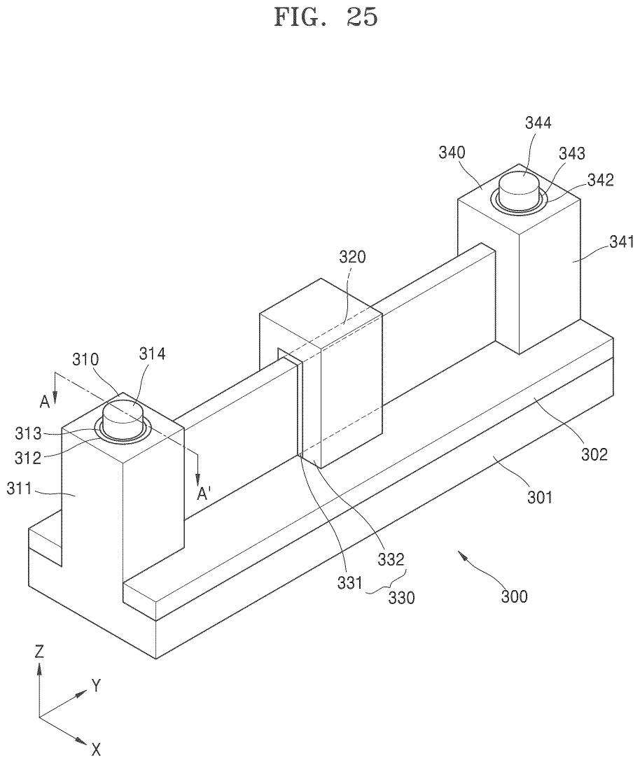

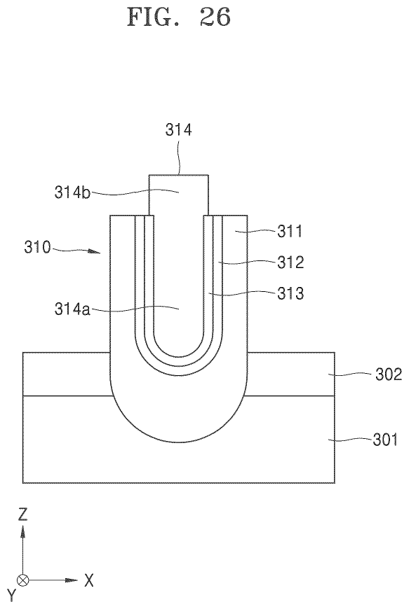

FIG. 25 is a schematic perspective view showing a structure of a field effect transistor 300 according to another embodiment. FIG. 26 is a schematic cross-sectional view taken along line A-A′ of the source structure 310 of FIG. 25.

Referring to FIG. 25, the field effect transistor 300 may include a substrate 301, a source structure 310 protruding in a Z-axis direction from an upper surface of the substrate 301, a drain structure 340 protruding in the Z-axis direction from the upper surface of the substrate 301, a channel 320 that protrudes in the Z-axis direction from the upper surface of the substrate 301 and has a bar shape extending in a Y-axis direction, and a gate structure 330 that surrounds and covers the channel 320. The field effect transistor 300 may further include a device isolation film 302 configured to electrical isolate the field effect transistor from other adjacent field effect transistors (not shown). The isolation film 302 may include an insulating dielectric material and may be disposed to extend in the Y-axis direction along both sides of the source structure 310, the channel 320, the gate structure 330, and the drain structure 340 on the upper surface of the substrate 301.

In at least one example, the field effect transistor 300 may be a Fin field effect transistor (FinFET).

The channel 320 may extend in the Y-axis direction and be connected between the source structure 310 and the drain structure 340. In other words, a first end of channel 320 may contact the source structure 310 and a second end of channel 320 may contact the drain structure 340. The channel 320 may include a P-type silicon semiconductor doped at a relatively low concentration or an N-type silicon semiconductor doped at a relatively low concentration but is not limited thereto.

The gate structure 330 may include a gate insulating film 331 covering the channel 320 between the source structure 310 and the drain structure 340, and a gate electrode 332 covering the gate insulating film 331. The gate insulating film 331 may be disposed to protrude from the upper surface of the substrate 301 to cover three sides of the channel 320, that is, both sides and an upper surface of the channel 320. The gate electrode 332 may be disposed to protrude from the upper surface of the substrate 301 to cover three sides of the gate insulating film 331, that is, both sides and an upper surface of the gate insulating film 331.

The source structure 310 may include a semiconductor layer 311, a source electrode 314 disposed within the semiconductor layer 311, a binary thirteenth silicide layer 313 disposed within the semiconductor layer 311 to surround the source electrode 314, and a ternary fourteenth silicide layer 312 disposed within the semiconductor layer 311 to surround the thirteenth silicide layer 313. Likewise, the drain structure 340 may include a semiconductor layer 341, a drain electrode 344 disposed within the semiconductor layer 341, a binary fifteenth silicide layer 343 disposed to surround the drain electrode 344 within the semiconductor layer 341, and a ternary sixteenth silicide layer 342 disposed to surround the fifteenth silicide layer 343 within the semiconductor layer 341.

The semiconductor layer 311 of the source structure 310 and the semiconductor layer 341 of the drain structure 340 may be arranged to protrude from the upper surface of the substrate 301 in the Z-axis direction. The semiconductor layer 311 of the source structure 310 and the semiconductor layer 341 of the drain structure 340 may include a relatively highly doped N-type semiconductor or a relatively highly doped P-type semiconductor. A portion of the semiconductor layer 311 of the source structure 310 and the semiconductor layer 341 of the drain structure 340 may extend in the Y-axis direction and be connected to the channel 320. A portion of the semiconductor layer 311 of the source structure 310 connected to the channel 320 and a portion of the semiconductor layer 341 of the drain structure 340 may have a width equal to a width of the channel 320 in the X-axis direction. The other portion of the semiconductor layer 311 of the source structure 310 and the other portion of the semiconductor layer 341 of the drain structure 340 opposite the channel 320 may have a width greater than the width of the channel 320.

Referring to FIG. 26, the source electrode 314 may have a rod shape extending in the Z-axis direction that is different from the direction in which the channel 320 extends. The source electrode 314 may include a first portion 314a located inside the semiconductor layer 311 and a second portion 314b protruding in the Z-axis direction above an upper surface of the semiconductor layer 311. The thirteenth silicide layer 313 may be disposed between the semiconductor layer 311 and the first portion 314a of the source electrode 314 to surround the first portion 314a of the source electrode 314. The fourteenth silicide layer 312 may be disposed between the semiconductor layer 311 and the thirteenth silicide layer 313 to surround the thirteenth silicide layer 313. The second portion 314b of the source electrode 314 may cover at least a portion of the thirteenth silicide layer 313 on the upper surface of the semiconductor layer 311. To this end, a diameter of the second portion 314b of the source electrode 314 may be greater than a diameter of the first portion 314a. The structure of the source structure 310 described above may be equally applied to the drain structure 340.

Referring to FIGS. 25 and 26, in at least one example, the semiconductor layer 311 of the source structure 310 and the semiconductor layer 341 of the drain structure 340 may correspond to the first material layer 30 of the layer structure 50 illustrated in FIG. 1.

In at least one example, the fourteenth silicide layer 312 of the source structure 310 and the sixteenth silicide layer 342 of the drain structure 340 may correspond to the first silicide layer 34A of the layer structure 50 illustrated in FIG. 1.

In at least one example, the thirteenth silicide layer 313 of the source structure 310 and the fifteenth silicide layer 343 of the drain structure 340 may correspond to the second silicide layer 34B of the layer structure 50 illustrated in FIG. 1.

In at least one example, the source electrode 314 of the source structure 310 and the drain electrode 344 of the drain structure 340 may correspond to the second material layer 38 of the layered structure 50 illustrated in FIG. 1.

Accordingly, a layer structure including the semiconductor layer 311, the fourteenth silicide layer 312, the thirteenth silicide layer 313, and the source electrode 314 sequentially stacked in a lateral direction of the source structure 310 may correspond to the layer structure 50 illustrated in FIG. 1. A layer structure including a semiconductor layer 341, a sixteenth silicide layer 342, a fifteenth silicide layer 343, and the drain electrode 344 sequentially stacked in the lateral direction of the drain structure 340 may also correspond to the layer structure 50 illustrated in FIG. 1.

In FIGS. 25 and 26, a FinFET structure has been described as an example, but the source structure 310 and the drain structure 340 shown in FIGS. 25 and 26 may also be applied to, for example, a gate-all-around FET (GAAFET) or multi-bridge channel FET (MBCFET) in addition to the FinFET.

In at least one example, the layer structure 50 illustrated in FIG. 1 may also be applied to a vertical structural type semiconductor device in which a metal layer is coupled to a side of a silicon semiconductor layer.

The layer structure 50 or field effect transistors described above may be applied to various electronic devices. As an example, the layer structure 50 or the field effect transistor described above may be applied to a driving integrated circuit of a display, a CMOS inverter, a CMOS SRAM device, and/or a CMOS NAND circuit, but is not limited thereto.

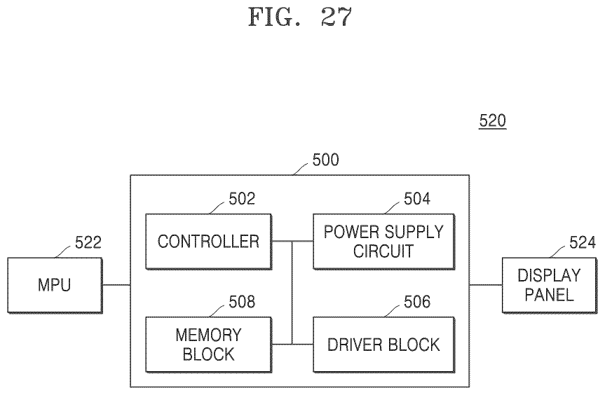

FIG. 27 is a schematic block diagram of a display driver IC (DDI) 500 and a display device 520 including the DDI 500, according to at least one embodiment.

Referring to FIG. 27, the DDI 500 may include a controller 502, a power supply circuit 504, a driver block 506, and a memory block 508. The controller 502 receives and decodes commands applied from the main processing unit (MPU) 522 and controls each block of the DDI 500 to implement operations according to the command. The power supply circuit 504 generates a drive voltage in response to control of controller 502. The driver block 506 drives a display panel 524 using the driving voltage generated by the power supply circuit 504 in response to the control by the controller 502. The display panel 524 may be, for example, a liquid crystal display panel, an organic light-emitting device (OLED) display panel, or a plasma display panel. The memory block 508 is a block that temporarily stores commands input to the controller 502 or control signals output from the controller 502, or stores necessary data, and may include memory such as RAM or ROM. The power supply circuit 504 and the driver block 506 may include the layer structure or the field effect transistor according to the example embodiments described above with reference to FIGS. 1 to 26.

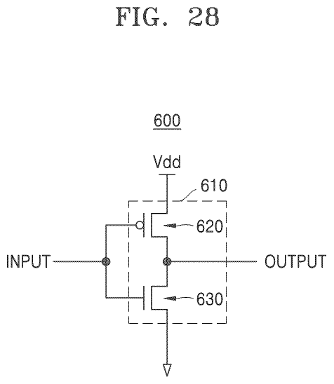

FIG. 28 is a circuit diagram of a CMOS (complementary metal-oxide-semiconductor) inverter 600 according to at least one embodiment.

Referring to FIG. 28, the CMOS inverter 600 includes a CMOS transistor 610. The CMOS transistor 610 consists of a PMOS (p-type metal-oxide-semiconductor) transistor 620 and an NMOS (n-type metal-oxide-semiconductor) transistor 630 connected between a power terminal Vdd and a ground terminal. The CMOS transistor 610 may include the layer structure or the field effect transistor according to the embodiments described above with reference to FIGS. 1 to 26.

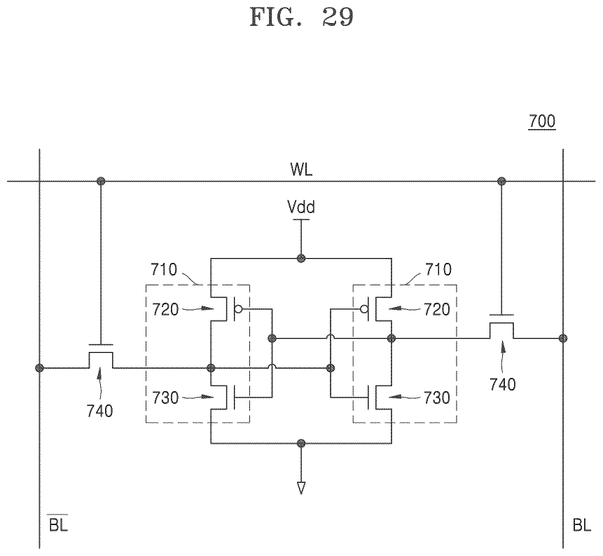

FIG. 29 is a circuit diagram of a CMOS SRAM device 700 according to at least embodiment.

Referring to FIG. 29, the CMOS SRAM (static random-access memory) device 700 includes a pair of driving transistors 710. The pair of driving transistors 710 includes a PMOS transistor 720 and an NMOS transistor 730 connected between a power terminal Vdd and a ground terminal, respectively. The CMOS SRAM device 700 may further include a pair of transfer transistors 740. A source of the transfer transistor 740 is cross connected to a common node of the PMOS transistor 720 and the NMOS transistor 730 that constitute the driving transistor 710. The power terminal Vdd is connected to the source of the PMOS transistor 720, and a ground terminal is connected to the source of the NMOS transistor 730. A word line WL may be connected to a gate of the pair of transfer transistors 740, and a bit line BL and an inverted bit line may be connected to a drain of each pair of transfer transistors 740, respectively. At least one of the driving transistor 710 and the transfer transistor 740 of the CMOS SRAM device 700 may include the layer structure or the field effect transistor according to the embodiments described above with reference to FIGS. 1 to 26.

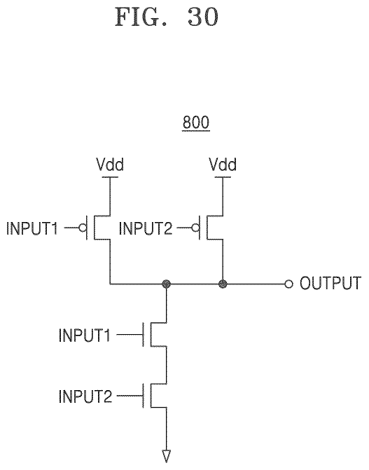

FIG. 30 is a circuit diagram of a CMOS NAND circuit 800 according to at least one embodiment.

Referring to FIG. 30, the CMOS NAND circuit 800 may include a pair of CMOS transistors through which different input signals are transmitted. The CMOS NAND circuit 800 may include the layer structure or the field effect transistor according to the embodiments described above with reference to FIGS. 1 to 26.

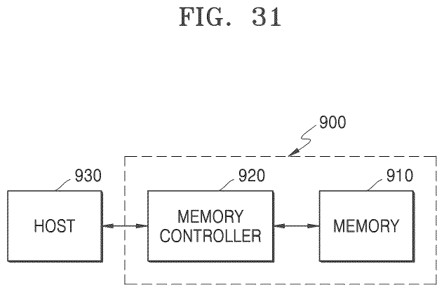

FIG. 31 is a block diagram illustrating an electronic device 900 according to at least one embodiment.

Referring to FIG. 31, the electronic device 900 includes a memory 910 and a memory controller 920. The memory controller 920 may control the memory 910 to read data from the memory 910 and/or write data to the memory 910 in response to a request from a host 930. At least one of the memory 910 and the memory controller 920 may include the layer structure or the field effect transistor according to the embodiments described above with reference to FIGS. 1 to 26.

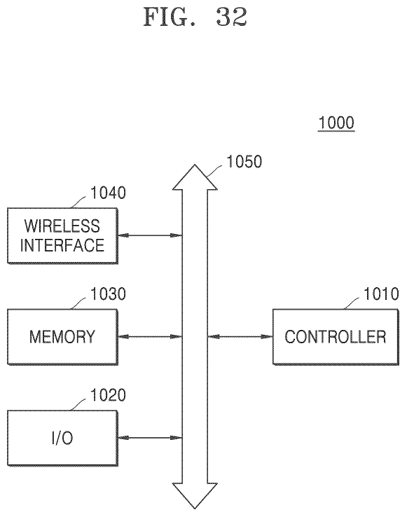

FIG. 32 is a block diagram of an electronic device 1000 according to at least one embodiment.

Referring to FIG. 32, the electronic device 1000 may configure a wireless communication device, or a device capable of transmitting and/or receiving information in a wireless environment. The electronic device 1000 includes a controller 1010, an input/output device (I/O) 1020, a memory 1030, and a wireless interface 1040, and these components are interconnected to each other through a bus 1050.

The controller 1010 may include at least one of a microprocessor, a digital signal processor, or a similar processing device. The input/output device 1020 may include at least one of a keypad, a keyboard, or a display. The memory 1030 may be used to store instructions executed by the controller 1010. For example, the memory 1030 may be used to store user data. The electronic device 1000 may use the wireless interface 1040 to transmit/receive data through a wireless communication network. The wireless interface 1040 may include an antenna and/or a wireless transceiver. In some embodiments, the electronic device 1000 may be used in a communication interface protocol of a third-generation communication system, for example, code division multiple access (CDMA), global system for mobile communications (GSM), north American digital cellular (NADC), extended-time division multiple access (E-TDMA), and/or wide band code division multiple access (WCDMA). The electronic device 1000 may include the layer structure or the field effect transistor according to the embodiments described above with reference to FIGS. 1 to 26.

The layer structure or the field effect transistor according to the embodiments described above may exhibit favorable electrical performance with an ultra-small structure and may be applied to integrated circuit devices, and may achieve miniaturization, low power, and high performance.

The disclosed layer structure includes a silicide layer including binary silicide and ternary silicide between a metal layer and a semiconductor layer. The ternary silicide and the binary silicide may be sequentially arranged in a direction from the semiconductor layer to the metal layer. In the case of the layer structure, the lattice constant mismatch between the binary silicide and the semiconductor layer may be reduced by the ternary silicide. Accordingly, the interfacial energy between the metal layer and the semiconductor layer may be lowered, thereby increasing the interfacial stability between the metal layer and the semiconductor layer, and thus specific resistance characteristics may also be improved.

In addition, due to the ternary silicide, the height of the Schottky barrier between the metal layer and the semiconductor layer may be lower compared to when only the binary silicide exists between the metal layer and the semiconductor layer. Accordingly, the contact resistance between the metal layer and the semiconductor layer may be lower than when only the binary silicide exists between the metal layer and the semiconductor layer.

Advantages of the layered structure may increase the operational stability of a semiconductor device or an electronic device to which the layered structure is applied, improve operating characteristics, and reduce operating power.

While the present inventive concepts have been particularly shown and described with reference to embodiments thereof, it should not be construed as being limited to the embodiments set forth herein rather than limiting the scope of the disclosure. Therefore, the scope of the present inventive concepts should not be defined by the described embodiments but should be defined by the technical spirit of the appended claims set forth herein.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A layer structure comprising:
a first material layer including silicon (Si);
a second material layer configured to face the first material layer and to form a Schottky barrier with the first material layer; and
a silicide layer between the first material layer and the second material layer,
wherein the silicide layer comprises an order “n” silicide and order “n+1” or greater silicide.

2. The layer structure of claim 1, wherein the silicide layer comprises:
a first silicide layer between the first material layer and the second material layer, the first silicide layer including the order n+1 or greater silicide; and
a second silicide layer between the first silicide layer and the second material layer, the second silicide layer including the order n silicide.

3. The layer structure of claim 2, wherein the first silicide layer comprises a mixture of the order “n+1” or greater silicide and the order n silicide.

4. The layer structure of claim 2, wherein
the order “n+1” or greater silicide has a composition formula of M1M2Siₓ, and
the order n silicide has a composition formula M2Siₓ,
wherein M1 and M2 include different elements.

5. The layer structure of claim 4, wherein
M1 has a first atomic radius R1, M2 has a second atomic radius R2, and the first atomic radius R1 is equal to or less than (1.15×R2), and
M1 and M2 have valence states that are compatible with each other.

6. The layer structure of claim 4, wherein M1 includes at least one of Co, Cr, Fe, Hf, Mn, Mo, Nb, Ni, Ru, Sc, Ta, Ti, V, W, Y or Zr.

7. The layer structure of claim 4, wherein M2 includes at least one of Sc, Ti, V, Co, Zr, Hf, or Y.

8. The layer structure of claim 4, wherein the second material layer comprises one of M1 and M2 as a metal component.

9. The layer structure of claim 4, wherein the second material layer comprises a metal component different from M1 and M2.

10. The layer structure of claim 4, wherein the order “n+1” or greater silicide further comprises an additional metal component different from M1 and M2.

11. The layer structure of claim 1, wherein the silicide layer is provided between (100) plane of the first material layer and the second material layer.

12. The layer structure of claim 1, wherein the first material layer comprises at least one of an undoped silicon layer, a silicon layer doped with a p-type dopant, or a silicon layer doped with an n-type dopant.

13. A method of manufacturing a layer structure, the method comprising:
distributing a first element on a first material layer, the first material layer comprising silicon (Si);
forming a second material layer covering the first element on the first material layer, the second material layer comprising a metal component; and
heat treating the second material layer such that a silicide including the first element is formed between the first and second material layers,
wherein the first element is a material different from the metal component.

14. The method of claim 13, further comprising:
Distributing a second element together with the first element on the first material layer; and
forming the second material layer to cover the first and second elements,
wherein the second element is a different element from the first element.

15. The method of claim 13, wherein the first element includes at least one of Co, Cr, Fe, Hf, Mn, Mo, Nb, Ni, Ru, Sc, Ta, Ti, V, W, Y or Zr.

16. The method of claim 13, wherein
the metal component comprises a metal element, and
the first element has a first atomic radius R1, and the metal element has a second atomic radius R2,
wherein the first atomic radius R1 is equal to or less than (1.15×R2), and
the first element and the metal element have valence electron states that are compatible with each other.

17. The method of claim 13, wherein the metal component includes at least one of Sc, Ti, V, Co, Zr, Hf, or Y.

18. The method of claim 13, wherein the heat treating is performed such that the silicide includes a ternary silicide including the first element, the metal component, and the silicon and a binary silicide including the metal component and the silicon.

19. A semiconductor device comprising the layer structure of claim 1.

20. An electronic device comprising the layer structure of claim 1.
